(19) United States
(12) Patent Application Publication
(10) Pub. No.: US 2017/0327943 A1
(43) Pub. Date: Nov. 16, 2017

(54) COATING STRUCTURE, HEAT EXCHANGER, AND METHOD FOR MANUFACTURING HEAT EXCHANGER

(71) Applicant: DENSO CORPORATION, Kariya-city, Aichi-pref. (JP)

(72) Inventors: Kazuaki KAFUKU, Kariya-city (JP); Yukihiro SANO, Kariya-city (JP); Takayuki HAYASHI, Kariya-city (JP); Manabu TOMISAKA, Kariya-city (JP); Ryonosuke TERA, Kariya-city (JP)

(21) Appl. No.: 15/531,197

(22) PCT Filed: Nov. 24, 2015
(86) PCT No.: PCT/JP2015/005826

§ 371 Date: May 26, 2017

(30) Foreign Application Priority Data
Dec. 2, 2014 (JP) 2014-243979
Oct. 30, 2015 (JP) 2015-215172

(51) Int. Cl. C23C 16/02; C23C 16/40; C23C 16/42; F01N 13/16

(52) U.S. Cl. CPC C23C 16/02; F01N 13/16; C23C 16/40; C23C 16/42

(57) ABSTRACT

A coating structure includes a base made of metal, a foundation layer provided on the base, and an insulation film provided on the foundation layer. The insulation film includes a plurality of layers, each layer of the plurality of layers being different in material, the plurality of layers being layered alternately with each other. The foundation layer is provided by a method other than a coating method using a surface chemical reaction occurring on the base, and a part of the foundation layer in contact with the base is amorphous. According to this, when a foreign material adheres on the base, the foreign material can be covered by the foundation layer. Since the insulation film is provided on the foundation layer, forming defects of the insulation film caused by the foreign material can be limited.

### CROSS REFERENCE TO RELATED APPLICATION

This application is based on and incorporates herein by reference Japanese Patent Applications No. 2014-243979 filed on Dec. 2, 2014, and No. 2015-215172 filed on Oct. 30, 2015.

### TECHNICAL FIELD

The present disclosure relates to a coating structure, a heat exchanger, and a method for manufacturing the heat exchanger.

### BACKGROUND ART

Conventionally, an insulation film is provided on a surface of a semiconductor substrate (for example, refer to Patent Document 1). Atomic layer deposition (Atomic Layer Deposition; ALD) is known as a method for forming an insulation film on the semiconductor substrate.

Resistance to corrosion is required for an exhaust gas flowing member (e.g. exhaust gas pipe) in which an exhaust gas discharged from an internal combustion engine of a vehicle flows. It may be considered that the insulation film having resistance to corrosion (in addition to insulation property) is provided on a surface of a base material of the exhaust gas flowing member in order to improve resistance to corrosion.

### PRIOR ART DOCUMENT

### Patent Document

Patent Document 1: Japanese Patent No. 2011-155033 A

### SUMMARY OF THE INVENTION

The inventors of the present disclosure have studied about a method for providing the insulation film on the surface of the exhaust gas flowing member by atomic layer deposition. However, since the exhaust gas flowing member is made of metal, its surface is uneven compared to a semiconductor substrate, and a foreign material may adhere to the surface. Moreover, forming of the film on the exhaust gas flowing member by atomic layer deposition is performed not in a clean room but under a usual circumstance of a factory. Therefore, according to the study by the inventors, when the insulation film is provided on the surface of the exhaust gas flowing member by atomic layer deposition, the following events may be occur.

In atomic layer deposition, a raw material gas is flown after water (water vapor) is absorbed on a surface of a base, and accordingly very thin film is formed on a surface of the base by a surface reaction between the raw material and water absorbed on the surface of the base. Therefore, atomic layer deposition is very likely to be affected by a condition of the surface of the base, and the surface reaction in atomic layer deposition may be interrupted by a foreign material when the foreign material exists on the surface of the base. Accordingly, the film may not be formed on a part where the foreign material exists, and forming defects (defects) of the insulation film may occur. The foreign material is, for example, oil that interrupts the adhesion of water (having water repellency), bonding agent, or carbon.

A first objective of the present disclosure is to provide a coating structure capable of limiting forming defects of an insulation film. A second objective is to provide a heat exchanger including the coating structure. Moreover, a third objective is to provide a method for manufacturing the heat exchanger.

A coating structure according to one aspect of the present disclosure includes a base made of metal, a foundation layer provided on the base, and an insulation film provided on the foundation layer. The insulation film includes a plurality of layers, each layer of the plurality of layers being different in material, the plurality of layers being layered alternately with each other. The foundation layer is provided by a method other than a coating method using a surface chemical reaction occurring on the base, and a part of the foundation layer is in contact with the base and is amorphous.

According to this, since the foundation layer is provided on the base, and since the foundation layer is provided by a method other than a coating method using a surface chemical reaction occurring on the base, a foreign material can be covered by the foundation layer even when the foreign material adheres on the base. Moreover, since the insulation film is provided on the foundation layer, a generation of forming defects due to the foreign material can be limited.

A heat exchanger according to another aspect of the present disclosure includes a base made of metal, a foundation layer provided on the base, and an insulation film provided on the foundation layer. The insulation film includes a plurality of layers, each layer of the plurality of layers being different in material, the plurality of layers being layered alternately with each other. A part of the foundation layer in contact with the base is made of silicon compound.

A method for manufacturing a heat exchanger according to another aspect of the present disclosure includes steps of: preparing a base made of metal; forming a foundation layer on the base; and layering alternately a plurality of layers to form an insulation film, each layer of the plurality of layers being different in material. In the step of forming the foundation layer, the foundation layer is formed such that a part of the foundation layer in contact with the base is silicon compound. When a foreign material adheres on a surface of the base, the foundation layer is formed so as to have a thickness covering whole of a surface of the foreign material.

According to this, since silicon compound is superior in a property for covering the foreign material and a property for adhering to the foreign material, the base and the foreign material are completely covered by the foundation layer even when the foreign material adheres to the base. Accordingly, the foreign material is not exposed from the foundation layer, and a surface of the foundation layer can be free from defects. Accordingly, forming defects of the insulation film formed on the foundation layer can be limited.

### BRIEF DESCRIPTION OF THE DRAWINGS

FIG. 1 is a sectional diagram illustrating an exhaust gas pipe according to a first embodiment of the present disclosure.

FIG. 2 is a sectional diagram illustrating the exhaust gas pipe in which a base is made of stainless steel according to the first embodiment.

FIG. 3 is a diagram illustrating a situation where the base on which a foundation layer is provided is submerged in sulfuric acid.

FIG. 4 is a diagram illustrating a relationship between thickness D of the foundation layer and a generation time of rust on the base.

FIG. 5 is a sectional diagram illustrating an exhaust gas pipe according to a second embodiment of the present embodiment.

FIG. 6 is a perspective diagram illustrating an EGR cooler according to a third embodiment of the present disclosure.

FIG. 7 is an explosive perspective diagram illustrating the EGR cooler shown in FIG. 6.

### EMBODIMENTS FOR EXPLOITATION OF THE INVENTION

Embodiments of the present disclosure will be described below referring to the drawings. In the respective embodiments, parts identical with or equivalent to each other may be assigned the same reference numeral in the drawings.

Hereinafter, multiple embodiments for implementing the present invention will be described referring to drawings. In the respective embodiments, a part that corresponds to a matter described in a preceding embodiment may be assigned the same reference numeral, and redundant explanation for the part may be omitted. When only a part of a configuration is described in an embodiment, another preceding embodiment may be applied to the other parts of the configuration. The parts may be combined even if it is not explicitly described that the parts can be combined. The embodiments may be partially combined even if it is not explicitly described that the embodiments can be combined, provided there is no harm in the combination.

### First Embodiment

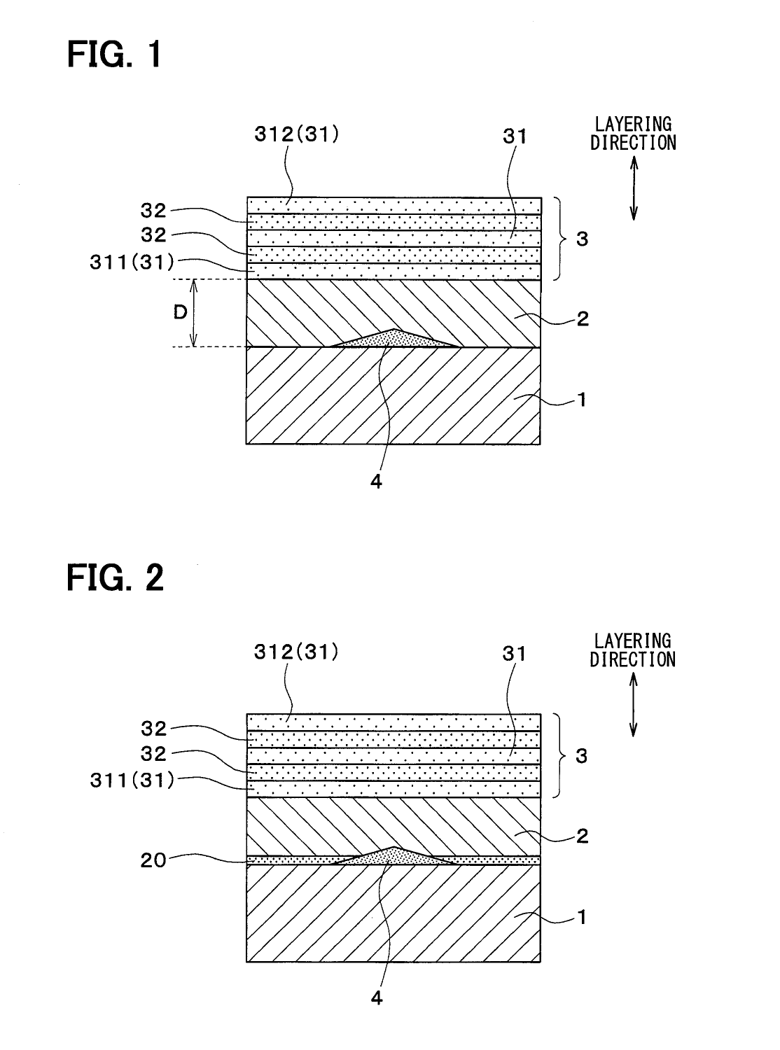

A first embodiment of the present disclosure will be described below referring to FIGS. 1 and 2. In the present embodiment, an example where a coating structure of the present disclosure is applied to an exhaust gas pipe in which an exhaust gas of an internal combustion engine flows will be described.

As shown in FIG. 1, the exhaust gas pipe includes a base 1 made of metal. In the present embodiment, the base 1 is made of stainless steel or aluminum.

A foundation layer 2 is provided on the base 1, i.e. on a surface of the base 1. On the foundation layer 2, i.e. on a reverse side of the surface of the foundation layer 2 facing the base 1, an insulation film 3 is provided.

The foundation layer 2 improves adhesiveness between the base 1 and the insulation film 3. The foundation layer 2 of the present embodiment is a single-layered film made of amorphous of silicon carbide (SiC) or aluminum oxide (Al₂O₃). A thickness D of the foundation layer 2 of the present embodiment, i.e. a length in a film layering direction (layering direction) (up-down direction of FIG. 1), is equal to or greater than 100 nm.

The foundation layer 2 is provided by a method other than coating methods using a surface chemical reaction occurring on the base 1 (such as atomic layer deposition (ALD)). In the present embodiment, the foundation layer 2 is provided by chemical vapor deposition (CVD) or sol-gel process.

The insulation film 3 is formed by alternately layering multiple layers 31, 32 which are made of materials different from each other. The insulation film 3 of the present embodiment is provided by atomic layer deposition. One of the layers 31 is Al₂O₃ layer, for example. The other of the layers 32 is TiO₂ layer, for example.

In the present embodiment, the insulation film 3 is formed by alternately layering an amorphous layer 31 made of amorphous and a crystalline layer 32 made of crystalline solid. The amorphous layer 31 has insulation properties.

Among multiple layers 31, 32 constituting the insulation film 3, a layer 311 contacting the foundation layer 2 is the amorphous layer 31. In other words, a part of the insulation film 3 in contact with the foundation layer 2 is amorphous.

Among multiple layers 31, 32 constituting the insulation film 3, a layer 312 positioned on an opposite side from the foundation layer 2 and farthermost from the foundation layer 2 in the layering direction is the amorphous layer 31. In other words, an outermost part of the insulation film 3 opposite from the foundation layer 2 in the layering direction is amorphous and is made of a material having insulation properties.

By forming the insulation film 3 from multiple layers 31, 32, lattice defects of the insulation film 3 can become unlikely to spread from the layer 311 to the layer 312 in the layering direction. In short, by alternately layering multiple layers 31, 32, a continuity of the defects can be interrupted. Especially, the crystalline layer 32 works as a layer cancelling the defects. Therefore, the insulation film 3 can be prevented from being cracked from the lattice defects. Accordingly, the insulation film 3 can be free from defects.

When the base 1 is made of stainless steel, a surface layer 20 including at least one of chromium (Cr), manganese (Mn), and oxygen (O) is provided on a surface of the base 1, as shown in FIG. 2. A thickness of the surface layer 20 is equal to or greater than 10 nm.

Specifically, the surface layer 20 is made of metal oxide. When the base 1 is made of stainless steel, the base 1 includes metal such as niobium (Nb), silicon (Si), molybdenum (Mo), nickel (Ni), copper (Cu), or titanium (Ti) in addition to chromium and manganese. The surface layer 20 is a layer of oxides including at least one metal included in the base 1.

The surface layer 20 is not limited to a form covering a part of a foreign material 4 as shown in FIG. 2. For example, the foreign material 4 may adhere on the surface layer 20.

As described above, in the present embodiment, the foundation layer 2 is provided on the base 1. The foundation layer 2 is provided by a method other than coating methods using a surface chemical reaction occurring on the base 1 (e.g. atomic layer deposition). According to this, even when the foreign material 4 such as carbon adheres on the base 1, the foreign material 4 can be covered by the foundation layer 2. Furthermore, forming defects of the insulation film 3 caused by the foreign material 4 can be prevented by providing the insulation film 3 on the foundation layer 2.

When the insulation film 3 is formed on the base 1, and when the foreign material 4 adheres on the base 1, the insulation film 3 cannot be formed on the foreign material 4 since the atomic layer deposition is a method in which the insulation film 3 is formed by a surface chemical reaction occurring on the base 1. In contrast, when the foundation layer 2 is provided by a coating method which does not use the surface chemical reaction occurring on the base 1 (e.g. chemical vapor deposition or sol-gel process), a surface of the foreign material 4 can be covered by the foundation layer 2. By providing the insulation film 3 on the foundation layer 2 via atomic layer deposition, the insulation film 3 can be provided on entire surface of the foundation layer 2. Accordingly, forming defects of the insulation film 3 can be limited.

Since the base 1 of the present embodiment is made of metal, its surface is uneven compared to a semiconductor substrate, for example. Therefore, when the insulation film 3 is provided directly on the base 1, uniformity of the insulation film 3 may be unlikely to be secured.

In contrast, in the present embodiment, the foundation layer 2 is formed on the base 1, and the insulation film 3 is provided on the foundation layer 2. Therefore, uniformity of the coating of the insulation film 3 can be secured.

In the present embodiment, the foundation layer 2 is a single-layered film made of amorphous. According to this, both a part of the foundation layer 2 contacting the base 1 and a part of the foundation layer 2 contacting the insulation film 3 can be amorphous.

Since the base 1 is made of metal, a metal oxide that is amorphous is provided on the surface of the base 1. Therefore, in the present embodiment, adhesiveness between the base 1 and the foundation layer 2 can be improved by forming the part of the foundation layer 2 contacting the foundation layer 2 by amorphous.

Moreover, since the part of the foundation layer 2 contacting the insulation film 3 is amorphous, adhesiveness between the foundation layer 2 and the insulation film 3 can be improved. Furthermore, in the present embodiment, since the part of the insulation film 3 contacting the foundation layer 2 is amorphous, adhesiveness between the foundation layer 2 and the insulation film 3 can be further improved.

The thickness D of the foundation layer 2 may be enough as long as the foundation layer 2 is capable of covering the surface of the foreign material 4, and the foreign material 4 may not be embedded in the foundation layer 2. Since the foreign material 4 has a variety of shapes, whole of the surface of the foreign material 4 can be covered by the foundation layer 2 whose thickness is set to be at or above 100 nm.

The reason for setting the thickness D of the foundation layer 2 at or above 100 nm will be described below. The inventors has provided the foundation layers 2 having various thicknesses and checked whether each of the foundation layers 2 covers entire surface of the foreign material 4.

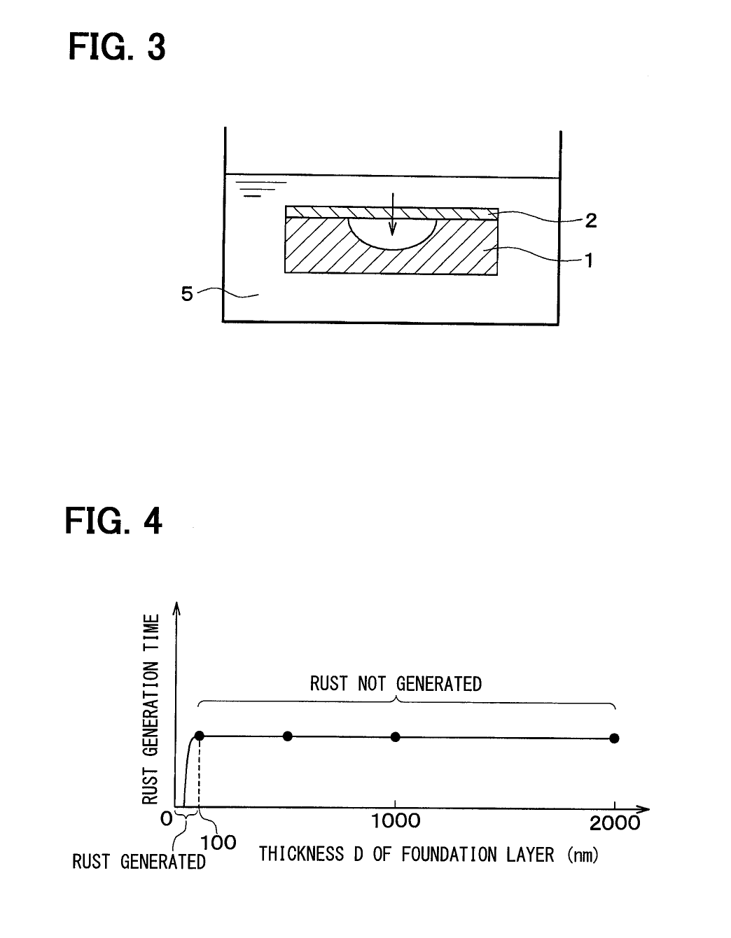

Specifically, as shown in FIG. 3, the base 1 on which the foundation layer is provided by chemical vapor deposition (CVD) is submerged in pH 1 sulfuric acid 5, and the inventors timed a generation of rust on the base 1. The rust is generated when the surface of the base 1 is melted by the sulfuric acid 5. The results are shown in FIG. 4.

A horizontal scale of FIG. 4 indicates the thickness D of the foundation layer 2. A vertical scale indicates time when the rust is generated on the base 1. When the value of the vertical scale is large, it takes long time to generate the rust, and entire surface of the foreign material 4 is covered by the foundation layer 2.

As shown in FIG. 4, when the thickness D of the foundation layer 2 is smaller than 100 nm, rust is generated on the base 1 soon after submerging the base 1 in the sulfuric acid 5. This is because the thickness of the foundation layer 2 is not enough to completely cover whole surface of the foreign material 4, and the foreign material 4 is melted by the sulfuric acid 5, and accordingly the base 1 covered by the foreign material 4 is melted by the sulfuric acid 5.

In contrast, when the thickness of the foundation layer 2 is equal to or greater than 100 nm, a time to generate rust is saturated. In other words, rust is not generated on the base 1. The inventors have submerged the base 1 including the foundation layer 2 in which the thickness D is set to be 100 nm, 500 nm, 1000 nm, or 2000 nm in the sulfuric acid 5 for 72 hours, but rust is not generated on any bases 1. Accordingly, the thickness D of the foundation layer 2 is preferred to be equal to or greater than 100 nm.

Regardless of size and shape of the foreign material 4, the thickness D of the foundation layer 2 is enough as long as the thickness D is at or above 100 nm. When the size of the foreign material 4 is above 100 nm, for example, a part of the foundation layer 2 corresponding to the foreign material 4 protrudes from the other part. However, the foundation layer 2 completely covers whole surface of the foreign material 4.

Moreover, at least one of the layers 31,32 constituting the insulation film 3 is amorphous layer 31 made of amorphous, and the insulation property and the resistance to corrosion can be secured. Furthermore, since the furthermost part of the insulation film 3 from the foundation layer 2 in the layering direction is made of material that is amorphous and has insulation property, the insulation property and the resistance to corrosion of the insulation film 3 can be further improved. Since the insulation property of the insulation film 3 is secured, the insulation film 3 is prevented from being corroded by electricity flowing in the insulation film 3.

### Second Embodiment

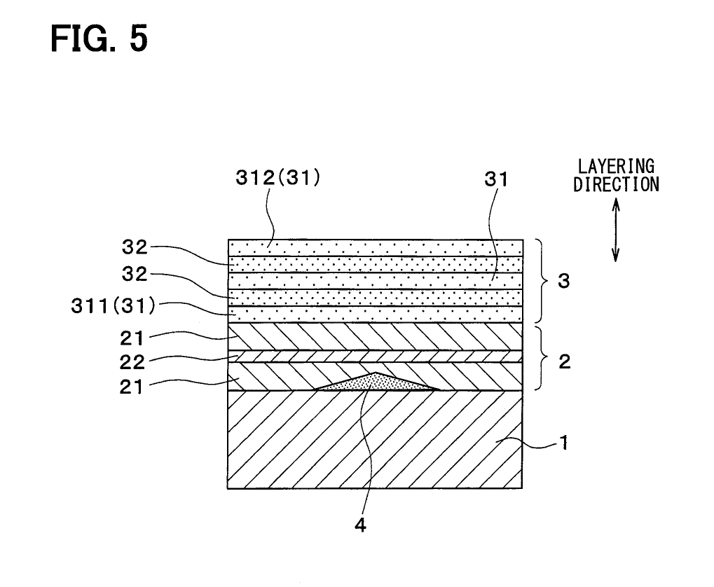

Next, a second embodiment of the present disclosure will be described referring to FIG. 5. Configurations of a foundation layer 2 of the second embodiment are different from the first embodiment.

As shown in FIG. 5, the foundation layer 2 of the present embodiment is formed by alternately layering amorphous layers 21 made of amorphous and a crystalline layer 22 made of crystalline layers 22. The amorphous layer 21 is provided in part of the foundation layer 2 contacting a base 1 and a part of the foundation layer 2 contacting an insulation film 3. That is, the part of the foundation layer 2 contacting the base 1 and the part of the foundation layer 2 contacting the insulation film 3 are amorphous.

As described above, since the part of the foundation layer 2 contacting the base 1 is amorphous, adhesiveness between the base 1 and the foundation layer 2 can be improved. Moreover, since the part of the foundation layer 2 contacting the insulation film 3 is amorphous, adhesiveness between the foundation layer 2 and the insulation film 3 can be improved.

### Third Embodiment

In a third embodiment of the present disclosure, parts different form the first and second embodiments will be described. In the present embodiment, an example where the above-described coating structure is applied to a cooling system or a heat exchanger of an air conditioner that is a product requiring resistance to corrosion will be described.

In the present embodiment, an EGR cooler is used as the heat exchanger, the EGR cooler cooling an exhaust gas by a cooling water (cooling medium) of an engine when the exhaust gas generated by a combustion in an engine (internal combustion engine) that is not shown is recirculated to the engine.

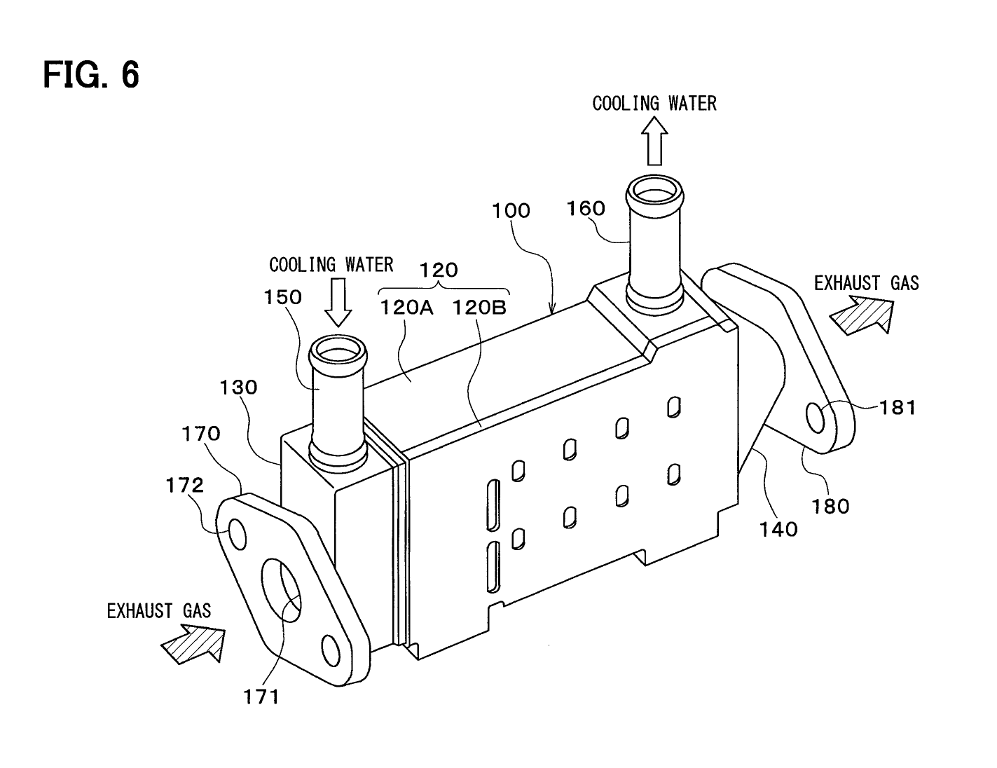

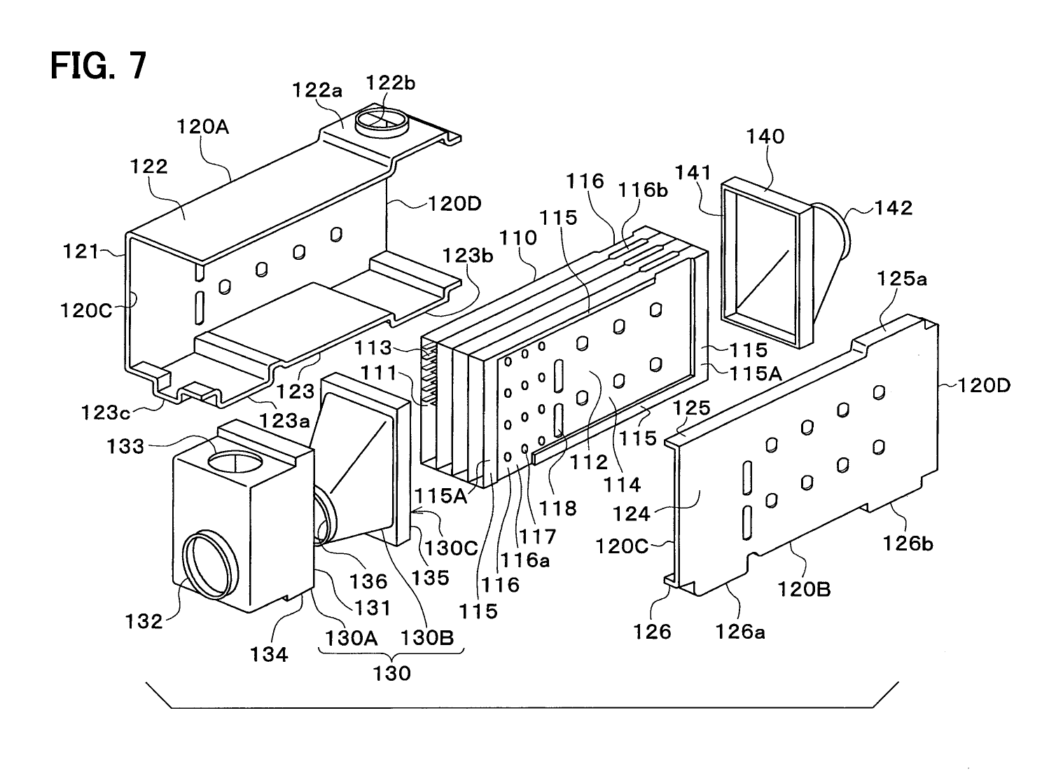

As shown in FIGS. 6 and 7, the EGR cooler 100 includes multiple exhaust gas tubes 110, a water tank 120, an inlet gas tank 130, an outlet gas tank 140, an inlet water pipe 150, an outlet water pipe 160, and flanges 170, 180.

As shown in FIG. 7, the exhaust gas tube 110 is a tube defining an exhaust gas passage 111. In the exhaust gas tube 110, an exhaust gas flows in the exhaust gas passage 111 inside the exhaust gas tube 110, and the cooling water flows outside the exhaust gas tube 110. According to this, the heat is exchanged between the exhaust gas and the cooling water through the exhaust gas tube 110.

In a cross-section sectioned in a direction perpendicular to an exhaust gas flowing direction, the exhaust gas tube 110 has a rectangular shape. Multiple exhaust gas tubes 110 are stacked in the direction (left-right direction of FIG. 7) perpendicular to the exhaust gas flowing direction. A cooling water passage 112 is defined by outer walls of exhaust gas tubes 110 adjacent to each other. According to this, the cooling water flows in the cooling water passage 112 between the exhaust gas tubes 110 adjacent to each other.

The exhaust gas tube 110 further includes a fin 113 provided in the exhaust gas passage 111. The fin 113 is bonded to an inner surface of the exhaust gas tube 110 by brazing. The fin 113 promotes the heat exchange between the exhaust gas and the cooling water. The fin 113 is provided in each of the exhaust gas tubes 110.

On a primary surface 114 of the exhaust gas tube 110, a protrusion portion 115 and a recess portion 116 are provided. The primary surface 114 is an outer surface of the exhaust gas tube 110 perpendicular to a stacking direction of the exhaust gas tubes 110. The protrusion portion 115 is an embossed portion formed by pressing so as to protrude outward from the primary surface 114. The protrusion portion 115 is formed in an outer peripheral portion of the primary surface 114 like a bund. The recess portion 116 is recessed from a protrusion top of the protrusion portion 115 toward the primary surface 114.

The recess portion 116 is provided in two parts that are opposite corners of the primary surface 114. Accordingly, multiple exhaust gas tubes 110 are stacked such that the protrusion potions 115 provided on the primary surfaces 114 contact with each other, and the protrusion portions 115 are integrated with each other.

The protrusion portions 115 provided in an end part in a longitudinal direction of the exhaust gas tubes 110 are connected to each other. According to this, a partitioning portion 115A separating an inside of the water tank 120 (cooling water passage 112) from an inside of the gas tanks 130, 140 is provided in the end parts of the exhaust gas tubes 110 in the longitudinal direction.

Between multiple exhaust gas tubes 110, a space is defined inside the protrusion portion 115. The space is the cooling water passage 112. An opening portion defined by one of the recess portion 116 (left lower side in FIG. 7) in the longitudinal direction of the exhaust gas tube 110 is an inlet side opening portion 116a through which an outside and the cooling water passage 112 are communicated with each other and the cooling water flows.

An opening portion defined by the other one of two recess portions 116 provided on the primary surface 114 in the longitudinal direction (right upper side in FIG. 7) of the exhaust gas tubes 110 is an outlet side opening portion 116b. In the exhaust gas passage 111 of the exhaust gas tube 110, a side into which the exhaust gas flows corresponds to the inlet side opening portion 116a, and a side from which the exhaust gas is discharged corresponds to the outlet side opening portion 116b.

A dimple 117 is provided in a part of the primary surface 114 of the exhaust gas tube 110 around the inlet side opening portion 116a, the dimple 117 being provided as a temperature decreasing portion that decreases a temperature of the cooling water in a temperature boundary layer on the outer surface of the exhaust gas tube 110. The dimple 117 is a protrusion portion having a circular cylindrical shape, for example, and multiple dimples 117 are arranged in a grid pattern. A protrusion dimension of the dimple 117 is equal to a protrusion dimension of the protrusion portion 115 on the outer peripheral portion of the exhaust gas tube 110.

On the primary surface 114 of the exhaust gas tube 110, a flow arranging portion 118 is provided so as to spread the cooling water to an entire surface of the primary surface 114 as much as possible and so as to guide the flow toward the outlet side opening portion 116b. The flow arranging portion 118 protrudes from the primary surface 114 similarly to the dimple 117.

The water tank 120 is a container having a cylindrical shape and accommodating multiple exhaust gas tubes 110 that are stacked with each other. As shown in FIG. 7, the water tank 120 includes a first water tank 120A and a second water tank 120B.

The first water tank 120A includes a body portion 121, an upper surface portion 122, and a lower surface portion 123. The body portion 121 faces the primary surface 114 of the exhaust gas tube 110. The upper surface portion 122 is bent at approximately right angle from an upper side end of the body portion 121 toward the exhaust gas tube 110. The lower surface portion 123 is bent at approximately right angle from a lower side end of the body portion 121 toward the exhaust gas tube 110. Accordingly, a cross-section of the first water tank 120A has C-shape.

In an end part of the upper surface portion 122 in the longitudinal direction on the side corresponding to the outlet side opening portion 116b, a bulging portion 122a protruding outward (upward) is provided. In the bulging portion 122a, a burring portion (flanged portion) and a pipe hole 122b to which the outlet water pipe 160 is connected are provided. Moreover, in both end portions of the lower surface portion 123 in the longitudinal direction, bulging portions 123a, 123b protruding outward (downward) are provided.

The second water tank 120B includes a body portion 124, an upper surface portion 125, and a lower surface portion 126. The body portion 124 faces the primary surface 114 of the exhaust gas tube 110. The upper surface portion 125 is bent at approximately right angle from an upper side end of the body portion 124 toward the exhaust gas tube 110. The lower surface portion 126 is bent at approximately right angle from a lower side end of the body portion 121 toward the exhaust gas tube 110. A cross-section of the second water tank 120B is C-shape whose depth is shallower than the first water tank 120A.

A bulging portion 125a protruding outward (upward) is provided in an end part of the upper surface portion 125 in the longitudinal direction on the side corresponding to the outlet side opening portion 116b, similarly to the first water tank 120A. Moreover, bulging portions 126a, 126b protruding outward (downward) is provided on both end portions of the lower surface portion 126 in the longitudinal direction, similarly to the first water tank 120A.

Open ends of the C-shapes of the first water tank 120A and the second water tank 120B are connected to each other to form the water tank 120 having a cylindrical shape whose cross-sectional shape is square. Both ends of the water tank 120 in the longitudinal direction are opening end portions 120C, 120D that is open toward an outside. In the opening end portion 120C adjacent to the inlet gas tank 130, the bulging portion 123c is provided as a water tank bulging portion.

The bulging portion 123c protrudes from a center part of a lower line of the opening end portion 120C having a square shape toward an outside (downward) of the lower line, and the bulging portion 123c is connected to the bulging portion 123a.

The inlet gas tank 130 includes an outside gas tank 130A and an inside gas tank 130B to have a double structure. The inlet gas tank 130 defines an exhaust gas passage 130C that distributes the exhaust gas from the exhaust gas tube to multiple exhaust gas tubes 110.

The outside gas tank 130A is a semi-container whose outside shape is cubic, and one surface of the outside gas tank 130A adjacent to the exhaust gas tube 110 is open. The opened part is an opening portion 131. The opening portion 131 has a square shape. The outside gas tank 130A includes a burring portion in a lower part of the other surface facing the opening portion 131, and the outside gas tank 130A includes a flange hole 132 having a circular shape and being configured to be connected to the flange 170. On an upper surface of the outside gas tank 130A, a pipe hole 133 configured to be connected to the inlet water pipe 150 is provided.

On an outside wall portion 134 that is a lower side of the outside gas tank 130A, a gas tank bulging portion is provided. The gas tank bulging portion protrudes from a center part of a lower line of the opening portion 131 having a square shape toward an outside (lower side), and the extent of protrusion of the gas tank bulging portion becomes small toward the flange hole 132. The gas tank bulging portion is provided on a surface of the outside gas tank 130A facing to a surface on which the pipe hole 133 is provided, i.e. the surface opposite to the surface on which the pipe hole 133 is provided.

The inside gas tank 130B has a funnel shape and defines the exhaust gas passage 130C therein. The inside gas tank 130B includes an opening portion 135 having a square shape on one surface adjacent to the exhaust gas tube 110. The inside gas tank 1306 includes a burring portion and a flange hole 136 on the other surface, the flange hole 136 having a circular shape and being connected to the flange 170. The other side surface may be a surface facing to the one surface.

The inside gas tank 1306 is inserted into an inside of the outside gas tank 130A. An outer peripheral surface of the opening portion 135 is connected to an inner peripheral surface of the opening portion 131 of the outside gas tank 130A excepting the gas tank bulging portion. An outer peripheral surface of the burring portion of the flange hole 136 is connected to an inner peripheral surface of the burring portion of the flange hole 132.

The inlet gas tank 130 having a double structure is a tank defining an outside space between the inside gas tank 130B and the outside gas tank 130A. The outside space is communicated with an outside of the inlet gas tank 130 and is communicated with an inner space of the water tank 120 through the gas tank bulging portion.

As shown in FIG. 6, the flange 170 configured to be connected to the exhaust gas pipe of the exhaust gas recirculation device is connected to the inlet gas tank 130. The flange 170 is a plate member whose outside shape is rhombus. The flange 170 includes a through-hole 171 provided at a center part of the flange 170, and a bolt hole 172 provided next to the through-hole 171. The bolt hole 172 is a female thread for screwing with a bolt.

The flange 170 is connected to the inlet gas tank 130 such that the through-hole 171 communicates with flange holes 132, 136 of the inlet gas tank 130. An inner peripheral surface of the opening portion 135 of the inlet gas tank 130 is connected to an outer peripheral surface of the partitioning portion 115A of multiple exhaust gas tubes 110 layered with each other. Accordingly, the exhaust gas passage 130C of the inside gas tank 130B is communicated with the exhaust gas passages 111 defined in each exhaust gas tube 110.

The outlet gas tank 140 has a funnel shape and defines the exhaust gas passage therein. As shown in FIG. 7, the outlet gas tank 140 includes an opening portion 141 having a square shape on one surface facing to the exhaust gas tube 110. The gas tank 140 includes a burring portion on the other surface, and a flange hole 142 having a circular shape configured to be connected to the flange 180. As shown in FIG. 6, the outlet gas tank 140 is connected to the flange 180 configured to be connected to an exhaust gas pipe that is connected to the exhaust gas recirculation device. The other surface may be a surface facing to the one surface.

The flange 180 is a plate member whose outer shape is rhombus, similarly to the flange 170. The flange 180 includes a through-hole at a center part, and a bolt hole 181 next to the through-hole. The flange 180 is connected to the outlet gas tank 140 such that the through-hole and the flange hole 142 of the outlet gas tank 140 are communicated with each other. An inner peripheral surface of the opening portion 141 of the outlet gas tank 140 is connected to an outer peripheral surface of the partitioning portion 115A of multiple exhaust gas tubes 110 layered with each other. Accordingly, the exhaust gas passage in the outside gas tank 140 is communicated with the exhaust gas passages 111 in each of the exhaust gas tubes 110.

The first water tank 120A and the second water tank 1206 are attached to each other so as to cover, in the layering direction, an outside of multiple exhaust gas tubes 110 layered with each other. According to this, the exhaust gas tube 110 is accommodated in the water tank 120. An inner peripheral surface of the opening end portion 120C of the water tank 120 is connected to an outer peripheral surface of the opening portion 131 of the outside gas tank 130A. Moreover, An inner peripheral surface of the opening end portion 120D of the water tank 120 is connected to an outer peripheral surface of the opening portion 141 of the outlet gas tank 140.

Accordingly, a space defined by the bulging portions 123a, 126a of the water tank 120 is communicated with the inlet side opening portion 116a provided on side surface portions of multiple exhaust gas tubes 110 layered with each other. A space defined by the bulging portions 122a, 125a of the water tank 120 is communicated with the outlet side opening portion 116b provided on side surface portions of multiple exhaust gas tubes 110 layered with each other. A space is defined between the side surface of the exhaust gas tube 110 and the bulging portions 123b, 126b.

Between the primary surface 114 of outermost one of the exhaust gas tubes 110 and the body portions 121, 124, the cooling water passage 112 that is the same as the cooling water passage 112 defined between the exhaust gas tubes 110 is defined. Moreover, between the side surface portion of the exhaust gas tube 110 on an upper side and upper surface portions 122, 125 of the water tanks 120A, 120B, and between the side surface portion of the exhaust gas tube 110 on a lower side and the lower surface portions 123, 126 of the water tanks 120A, 120B, spaces are provided. The space defined in the water tank 120 and outside the exhaust tube 110 is the inner space of the water tank 120.

Moreover, the inner peripheral surface of the bulging portion 123c of the water tank 120 is connected to the outer peripheral surface of the gas tank bulging portion of the outside gas tank 130A, and accordingly the bulging portion 123c is connected to the gas tank bulging portion. The bulging portion 123c and the gas tank bulging portion define the passage of the cooling water. Through the passage of the cooling water, the space defined by the bulging portions 123a, 126a of the water tank 120 is communicated with an outer space in the inlet gas tank 130.

The inlet water pipe 150 is a pipe member into which the cooling water flowing from the engine flows. An end portion of the inlet water pipe 150 is inserted into and connected to the pipe hole 133 of the outside gas tank 130A. The inlet water pipe 150 is communicated with the outer space in the inlet gas tank 130.

The outlet water pipe 160 is a pipe member from which the cooling water flowing in the cooling water passage 112 of the exhaust gas tube 110 flows out. An end portion of the outlet water pipe 160 is inserted into the pipe hole 122b provided in the bulging portion 122a of the water tank 120. The outlet water pipe 160 is communicated with the space defined by the bulging portions 122a, 125a of the water tank 120.

Whole structure of the EGR cooler 100 is described above. Each of the members 110-180 constituting the EGR cooler 100 is formed from the base 1. Each of the members 110-180 is made of stainless, aluminum material or aluminum alloy material, for example, the aluminum material and aluminum alloy material being light, superior in thermal conductivity, and cheap. The members 110-180 are bonded by brazing or welding with each other. In other words, the base 1 includes multiple members 110-180 brazed with each other.

Next, a method for applying the above-described coating structure to the EGR cooler 100 in which the members 110-180 are brazed with each other. First, the EGR cooler 100 is prepared as the base 1 made of metal.

In a brazing step, the base 1 is placed in a furnace that is at a high temperature. Therefore, in a step where the EGR cooler 100 is prepared, the surface layer 20 may be provided on the surface of the base 1, or the surface layer 20 may be provided.

Next, the foundation layer 2 is formed on the base 1. Here, the foundation layer 2 is formed such that a part of the foundation layer 2 is in contact with the base 1 and is silicon compound. Moreover, when the foreign material 4 adheres on the surface of the base 1, the foundation layer 2 is formed so as to have a thickness capable of covering whole of the surface of the foreign material 4. As described above, whole of the surface of the foreign material 4 can be covered by forming the foundation layer 2 having the thickness D at or above 100 nm.

Subsequently, multiple layers 31, 32 are alternately layered on the foundation layer 2, each layer of the layers 31, 32 being different in material. According to this, the insulation film 3 is provided. As a result, the EGR cooler 100 having the coating structure is manufactured.

Accordingly, a part of the foundation layer 2 of the present embodiment that is in contact with the base 1 is made of silicon compound. According to this, since the silicon compound is superior in a property for covering and adhering to the foreign material 4, the base 1 and the foreign material 4 are completely covered by the foundation layer 2 even when the foreign material 4 adheres to the base 1. Therefore, the foreign material 4 is not exposed from the foundation layer 2, and defects on the surface of the foundation layer 2 can be avoided. Accordingly, forming defects of the insulation film 3 provided on the foundation layer 2 can be limited.

In the present embodiment, whole of the foundation layer 2 is made of silicon compound. The foundation layer 2 may be formed from multiple layers, similarly to the second embodiment.

When the base 1 is brazed, carbide is likely to remain as the foreign material 4 on the surface of the base 1. Under such situation, the foreign material 4 can be completely covered by the foundation layer 2, and the insulation film 3 can be provided on the whole of the foundation layer 2.

In order to coat a heat exchanger such as the EGR cooler 100, a heat resistance under high temperature, and resistance properties against low temperature, cold heat, vibration, and pressure are needed. However, silicon compound is superior in heat resistance, and resistance properties against low temperature, cold heat, vibration, and pressure. Accordingly, adhesiveness of the foundation layer 2 to the base 1 can be secured.

In the present embodiment, the silicon compound is amorphous. According to this, adhesiveness of the foundation layer 2 to the base 1 can be improved. Accordingly, a generation of crack in the foundation layer 2 can be limited, and the foundation layer 2 can be prevented from removing from the base 1.

The silicon compound may be at least one of SiC, SiN, SiCN, SiO, and SiON. The silicon compound may be mixture including some of SiC, SiN, SiCN, SiO, and SiON. Since the foundation layer 2 is made of such materials, adhesiveness of the foundation layer 2 to the foreign material 4 whose primary element is carbon can be secured.

The present disclosure is not limited to the above-described embodiments, and the present disclosure can be modified within the scope of the present disclosure, such as described below.
(1) In the above-described embodiments, the coating structure of the present disclosure is applied to the exhaust gas pipe, but the application of the coating structure is not limited to this. For example, the coating structure of the present disclosure may be applied to an EGR valve provided in an EGR (Exhaust Gas Recirculation) device that recirculates a part of the exhaust gas from the internal combustion engine to an air intake side.
(2) The foundation layer 2 of the third embodiment may be applied to the coating structure described in the first or second embodiments. That is, a part of the foundation layer 2 of the first or second embodiment in contact with the base 1 may be made of silicon compound. Moreover, silicon compound is not limited to amorphous and may be polycrystalline form. When the silicon compound is polycrystalline form, the surface of the foundation layer 2 is uneven, and accordingly adhesiveness of the foundation layer 2 to the insulation film 3 can be improved by anchor effect.
(3) In the third embodiment, the exhaust gas heat exchanger is described as a heat exchanger, but it is an example. The heat exchanger is not limited to one of exhaust gas type, and may be one used for other purpose.

Although the present disclosure is described in connection with the preferred embodiments thereof, it is to be noted that the present disclosure is not limited to the embodiments and the configurations. The present disclosure includes various changes and modifications within the equivalent. Moreover, other combinations and configurations, including more, less or only a single element, are also within the spirit and scope of the present disclosure.

What is claimed is:

1. A coating structure comprising:
a base made of metal;
a foundation layer provided on the base; and
an insulation film provided on the foundation layer, wherein
the insulation film includes a plurality of layers, each layer of the plurality of layers being different in material, the plurality of layers being layered alternately,
the foundation layer is provided by a method other than a coating method using a surface chemical reaction occurring on the base, and
a part of the foundation layer is in contact with the base and is amorphous,
the base is made of stainless steel or aluminum, and
the foundation layer is made of silicon compound or aluminum oxide.

2. The coating structure according to claim 1, wherein at least one layer of the plurality of layers of the insulation film is amorphous.

3. The coating structure according to claim 1, wherein a part of the foundation layer is in contact with the insulation film and is amorphous.

4. The coating structure according to claim 1, wherein a part of the insulation film is in contact with the foundation layer and is amorphous.

5. The coating structure according to claim 1, wherein a thickness of the foundation layer is equal to or greater than 100 nm.

6. The coating structure according to claim 1, wherein an outermost part of the insulation film opposite from the foundation layer is made of a material that is amorphous and has an insulation property.

7. (canceled)

8. The coating structure according to claim 1, wherein
the base is made of stainless steel,
the base includes a surface layer on a surface, the surface layer including at least one of chromium, manganese, and oxygen, and
a thickness of the surface layer is equal to or greater than 10 nm.

9. The coating structure according to claim 1, wherein the insulation film is provided by atomic layer deposition.

10. A heat exchanger comprising:
a base made of metal,
a foundation layer provided on the base; and
an insulation film provided on the foundation layer, wherein
the insulation film includes a plurality of layers, each layer of the plurality of layers being different in material, the plurality of layers being layered alternately, and
a part of the foundation layer is in contact with the base and is made of silicon compound.

11. The heat exchanger according to claim 10, wherein the silicon compound is amorphous.

12. The heat exchanger according to claim 10, wherein the silicon compound includes at least one of SiC, SiN, SiCN, SiO, and SiON.

13. The heat exchanger according to claim 10, wherein the base is formed of a plurality of members brazed to each other.

14. A method for manufacturing a heat exchanger, the method comprising:
preparing a base made of metal;
forming a foundation layer on the base; and
layering a plurality of layers alternately to form an insulation film on the foundation layer by atomic layer deposition, each layer of the plurality of layers being different in material, wherein
the forming of the foundation layer includes:
making a part of the foundation layer be in contact with the base and be made of silicon compound, and
making a thickness of the foundation layer to cover a whole surface of a foreign material when the foreign material adheres to a surface of the base.
